(19) United States
(12) Patent Application Publication
(10) Pub. No.: US 2024/0234279 A9
(43) Pub. Date: Jul. 11, 2024

(54) SEMICONDUCTOR PACKAGE

(71) Applicant: Samsung Electronics Co., Ltd., Suwon-si (KR)

(72) Inventors: Choongbin YIM, Suwon-si (KR); Jiyong PARK, Suwon-si (KR)

(73) Assignee: Samsung Electronics Co., Ltd., Suwon-si (KR)

(21) Appl. No.: 18/490,995

(22) Filed: Oct. 20, 2023

(30) Foreign Application Priority Data
Oct. 21, 2022 (KR) 10-2022-0136829

(51) Int. Cl. H01L 23/498; H01L 23/00; H01L 23/31; H01L 25/10

(52) U.S. Cl. CPC H01L 23/49822; H01L 23/3135; H01L 24/16; H01L 24/32; H01L 24/48; H01L 24/73; H01L 25/105; H01L 2224/16227; H01L 2224/32225; H01L 2224/48227; H01L 2224/73204; H01L 2224/73257; H01L 2224/73265; H01L 2225/1023; H01L 2225/1041; H01L 2225/1058; H01L 2924/15174; H01L 2924/15184

(57) ABSTRACT

A semiconductor package includes a first redistribution structure including a first redistribution layer and a first redistribution bonding pad, the first redistribution bonding pad electrically connected to the first redistribution layer, a first semiconductor chip on the first redistribution structure, and a second redistribution structure on the first semiconductor chip, the second redistribution structure including a second redistribution layer and a second redistribution bonding pad, the second redistribution layer electrically connected to the second redistribution layer. The semiconductor package includes a bonding wire electrically connecting the second redistribution bonding pad and the first redistribution bonding pad to each other, and a molding layer covering at least a portion the first semiconductor chip, the second redistribution structure, and the bonding wire on the first redistribution structure.

### CROSS-REFERENCE TO RELATED APPLICATION

This application is based on and claims priority under 35 U.S.C. § 119 to Korean Patent Application No. 10-2022-0136829, filed on Oct. 21, 2022, in the Korean Intellectual Property Office, the disclosure of which is incorporated by reference herein in its entirety.

### FIELD

The inventive concepts relate to a semiconductor package, including a semiconductor package in which a semiconductor chip and a redistribution structure may be electrically connected to each other with reliability.

### BACKGROUND

With the rapid development of the electronics industry and the needs of users, electronic devices have become smaller, more multifunctional, and larger in capacity, and thus, highly integrated semiconductor chips have been desired or required. Accordingly, a semiconductor package in which a redistribution structure is arranged on a semiconductor chip, and the semiconductor chip is electrically connected to the redistribution structure with reliability is proposed.

### SUMMARY

The inventive concepts provide a semiconductor package in which a semiconductor chip and a redistribution structure may be electrically connected to each other with reliability.

According to an aspect of the inventive concepts, a semiconductor package includes a first redistribution structure comprising a first redistribution layer and a first redistribution bonding pad, the first redistribution bonding pad electrically connected to the first redistribution layer, a first semiconductor chip on the first redistribution structure, a second redistribution structure on the first semiconductor chip, the second redistribution structure comprising a second redistribution layer and a second redistribution bonding pad, the second redistribution layer electrically connected to the second redistribution layer, a bonding wire electrically connecting the second redistribution bonding pad and the first redistribution bonding pad to each other, and a molding layer covering at least a portion the first semiconductor chip, the second redistribution structure, and the bonding wire on the first redistribution structure.

According to another aspect of the inventive concepts, a semiconductor package includes a first redistribution structure including a fan-in region and a fan-out region, the fan-in region including at least two sides and the fan-out region on each of the at least two sides of the fan-in region, the first redistribution structure comprising a first redistribution insulating layer, a first redistribution layer insulated by the first redistribution insulating layer, and a first redistribution bonding pad electrically connected to the first redistribution layer, the first redistribution bonding pad on an upper portion of the first redistribution insulating layer in the fan-out region. The semiconductor package includes a first semiconductor chip on the first redistribution structure in the fan-in region, a second redistribution structure on the first semiconductor chip in the fan-in region and the fan-out region, the second redistribution structure comprising a second redistribution insulating layer, a second redistribution layer insulated by the second redistribution insulating layer, and a second redistribution bonding pad electrically connected to the second redistribution layer, the second redistribution layer on an upper portion of the second redistribution insulating layer in the fan-out region, a bonding wire electrically connecting the second redistribution bonding pad in the fan-out region and the first redistribution bonding pad in the fan-out region to each other, and a molding layer covering at least a portion of the first semiconductor chip, the second redistribution structure, and the bonding wire on the first redistribution structure in the fan-in region and the fan-out region.

According to another aspect of the inventive concepts, a semiconductor package includes a first redistribution structure including a fan-in region and a fan-out region, the fan-in region including at least two sides, and the fan-out region on each of the at least two sides of the fan-in region, the first redistribution structure comprising a first redistribution insulating layer, a first redistribution layer insulated by the first redistribution insulating layer, a first connection pad electrically connected to the first redistribution layer in the fan-in region, and a first redistribution bonding pad electrically connected to the first redistribution layer in the fan-out region. The semiconductor package includes a first semiconductor chip on the first redistribution structure in the fan-in region, the first semiconductor chip electrically connected to the first connection pad through a first chip connection terminal, a second redistribution structure on the first semiconductor chip in the fan-in region and the fan-out region, the second redistribution structure comprising a second redistribution insulating layer, a second redistribution layer insulated by the second redistribution insulating layer, a third connection pad electrically connected to the second redistribution layer in the fan-in region, and a second redistribution bonding pad electrically connected to the second redistribution layer in the fan-out region. The semiconductor package includes a bonding wire electrically connecting the second redistribution bonding pad in the fan-out region and the first redistribution bonding pad in the fan-out region to each other, and a molding layer covering at least a portion of the first semiconductor chip, the second redistribution structure, and the bonding wire on the first redistribution structure in the fan-in region and the fan-out region, the molding layer having a connection hole exposing the third connection pad. an upper width of the connection hole is greater than a lower width of the connection hole, the connection hole includes at least two sidewalls, and the at least two sidewalls of the connection hole are inclined.

### BRIEF DESCRIPTION OF THE DRAWINGS

Some example embodiments of the inventive concepts will be more clearly understood from the following detailed description taken in conjunction with the accompanying drawings in which:

FIG. 1 is a cross-sectional view of a semiconductor package according to an example embodiment;

FIG. 2 is an enlarged view of a portion of the semiconductor package of FIG. 1;

FIG. 3 is a cross-sectional view of a semiconductor package according to an example embodiment;

FIG. 4 is an enlarged view of a portion of the semiconductor package of FIG. 3;

FIGS. 5 to 9 are cross-sectional views for explaining a method of manufacturing the semiconductor package of FIGS. 1 and 2;

FIGS. 10 to 12 are cross-sectional views for explaining a method of manufacturing the semiconductor package of FIGS. 3 and 4;

FIG. 13 is a cross-sectional view of a semiconductor package according to an example embodiment;

FIG. 14 is a cross-sectional view for explaining a method of manufacturing the semiconductor package of FIG. 13;

FIG. 15 is a cross-sectional view of a semiconductor package according to an example embodiment;

FIG. 16 is a cross-sectional view for explaining a method of manufacturing the semiconductor package of FIG. 15;

FIG. 17 is a block diagram schematically illustrating a configuration of a semiconductor package according to an example embodiment; and

FIG. 18 is a block diagram schematically illustrating a configuration of a semiconductor package according to an example embodiment.

### DETAILED DESCRIPTION

Hereinafter, some example embodiments of the inventive concepts are described in detail with reference to the accompanying drawings Like reference numerals in the drawings denote like elements, and thus their description will be omitted.

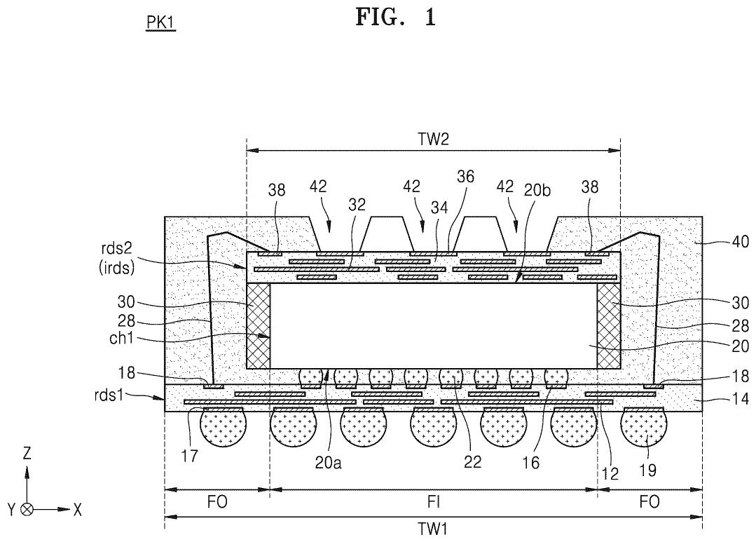

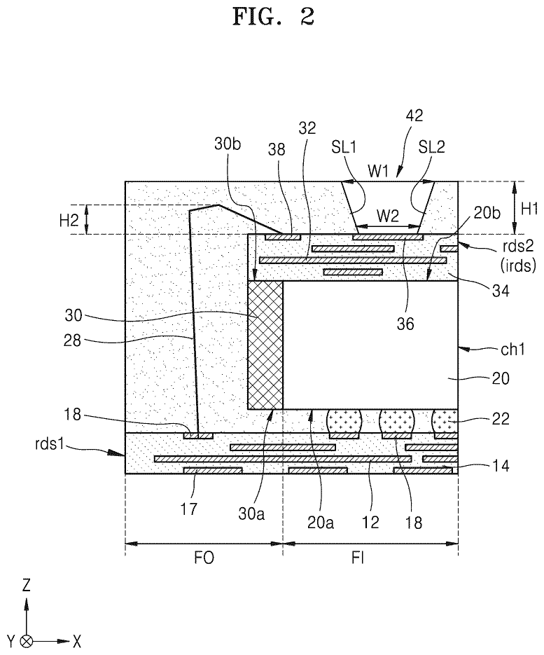

FIG. 1 is a cross-sectional view of a semiconductor package according to an example embodiment, and FIG. 2 is an enlarged view of a portion of the semiconductor package of FIG. 1.

In particular, a semiconductor package PK1 may include a first redistribution structure rds1, a first semiconductor chip ch1, a second redistribution structure rds2, a bonding wire 28, a first molding layer 30 and a second molding layer 40. In the following drawings, X and Y directions may be directions parallel to the surface of the first redistribution structure rds1, and a Z direction may be a direction perpendicular to the surface of the first redistribution structure rds1.

The semiconductor package PK1 may include the first redistribution structure rds1 and the second redistribution structure rds2, each extending to the outside (or the periphery) of the first semiconductor chip ch1. Accordingly, the semiconductor package PK1 may be a fan-out semiconductor package. Also, the semiconductor package PK1 may be a wafer level package in which a package is manufactured at a wafer level. Collectively, the semiconductor package PK1 may be a fan-out wafer level-package (FOWLP) type. Hereinafter, the structure of the semiconductor package PK1 is described in detail.

The first redistribution structure rds1 may include a fan-in region FI and a fan-out region FO. The fan-in region FI may be an area where the first semiconductor chip ch1 is mounted. The fan-out region FO may be on both sides of the fan-in region FI. The fan-out region FO may surround the fan-in region FI in a plan view. The fan-out region FO may be an area where the molding layers 30 and 40 are formed.

The first redistribution structure rds1 may include a first redistribution layer 12 and a first redistribution insulating layer 14. The first redistribution structure rds1 may have a first width TW1. The first width TW1 of the first redistribution structure rds1 may be in a range of tens of millimeters (mm) to hundreds of mm. The first redistribution layer 12 may be formed inside the first redistribution insulating layer 14. The first redistribution layer 12 may be insulated by the first redistribution insulating layer 14.

The first redistribution layer 12 may include multiple layers inside the first redistribution insulating layer 14. The first redistribution layer 12 may include, for example, a metal layer including a material, such as copper, nickel, stainless steel, and beryllium copper. The first redistribution insulating layer 14 may include an insulating polymer or an insulating material containing silicon. The insulating polymer may include, for example, photosensitive polyimide (PSPI), polybenzoxazole (PBO), a phenolic polymer, and/or a benzocyclobutene (BCB)-based polymer. The insulating material containing silicon may include silicon oxide, silicon nitride, silicon oxynitride, and/or tetraethyl orthosilicate (TEOS). Example embodiments are not limited to the above example materials.

The first redistribution structure rds1 may include a first connection pad 16, a second connection pad 17, and a first redistribution bonding pad 18. The first connection pad 16 may be positioned at an upper portion of the first redistribution structure rds1. The first connection pad 16 may be positioned in the fan-in region FI. The first connection pad 16 may be a portion of the first redistribution layer 12.

The first connection pad 16 may be electrically connected to the first semiconductor chip ch1 through a first chip connection terminal 22. A plurality of first chip connection terminals 22 may be provided. The first chip connection terminal 22 may include at least one of a solder, a bump, and a pillar.

The second connection pad 17 may be positioned at a lower portion of the first redistribution structure rds1. The second connection pad 17 may be positioned in the fan-in region FI and the fan-out region FO. The second connection pad 17 may be a portion of the first redistribution layer 12. The second connection pad 17 may be electrically connected to a first external connection terminal 19. A plurality of first external connection terminals 19 may be provided. The first external connection terminal 19 may include at least one of a solder, a bump, and a pillar.

The first redistribution bonding pad 18 may be positioned at the upper portion of the first redistribution structure rds1. The first redistribution bonding pad 18 may be positioned in the fan-out region FO. The first redistribution bonding pad 18 may be formed in all fan-out regions FO on both sides of the fan-in region FI. The first redistribution bonding pad 18 may be a portion of the first redistribution layer 12. The first redistribution bonding pad 18 may be a pad to which the bonding wire 28 is bonded.

The first semiconductor chip ch1 may be arranged on the first redistribution structure rds1. The first chip connection terminal 22 may be formed on a lower portion of the first semiconductor chip ch1. The first semiconductor chip ch1 may be electrically connected to the first connection pad 16 of the first redistribution structure rds1 through the first chip connection terminal 22.

The first semiconductor chip ch1 may include a first semiconductor substrate 20. The first semiconductor substrate 20 may include a semiconductor element, such as germanium (Ge), or a compound semiconductor, such as silicon carbide (SiC), gallium arsenide (GaAs), indium arsenide (InAs), and indium phosphide (InP), but example embodiments are not limited thereto. The first semiconductor substrate 20 may have a silicon-on-insulator (SOI) structure.

The first semiconductor substrate 20 may include a conductive region, for example, an impurity-doped well. The first semiconductor substrate 20 may include various device isolation structures, such as a shallow trench isolation (STI) structure.

The first semiconductor substrate 20 may have a lower surface 20a and an upper surface 20b. The lower surface 20a of the first semiconductor substrate 20 may be an active surface on which an active element is formed, and the upper surface 20b of the first semiconductor substrate 20 may be an inactive surface on which an active element is not formed. A plurality of individual devices (not shown) of various types may be formed on the lower surface 20a of the first semiconductor substrate 20.

The plurality of individual devices may include various microelectronic devices, for example, a metal-oxide-semiconductor field effect transistor (MOSFET), such as a complementary metal-insulator-semiconductor (CMOS) transistor, a system large scale integration (LSI), an image sensor, such as a CMOS imaging sensor (CIS), a micro-electro-mechanical system (MEMS), an active device, a passive device, or the like.

In some example embodiments, the first semiconductor chip ch1 may be a central processor unit (CPU) chip, a micro processor unit (MPU) chip, a graphic processor unit (GPU) chip, or an application processor (AP) chip.

The first molding layer 30 may be formed on each of both sidewalls of the first semiconductor chip ch1. As shown in FIG. 2, the first molding layer 30 may include a lower surface 30a and an upper surface 30b. The lower surface 30a of the first molding layer 30 may be coplanar or substantially coplanar with the lower surface 20a of the first semiconductor substrate 20. The upper surface 30b of the first molding layer 30 may be coplanar or substantially coplanar with the upper surface 20b of the first semiconductor substrate 20. The first molding layer 30 may protect both sidewalls of the first semiconductor chip ch1. The first molding layer 30 may include an insulating polymer. In some example embodiments, the first molding layer 30 may include an epoxy molding compound (EMC).

The second redistribution structure rds2 may be arranged on the upper surface 20b of the first semiconductor chip ch1 and the upper surface 30b of the first molding layer 30. The second redistribution structure rds2 may be an interposer redistribution structure irds. An upper semiconductor package may be mounted on the second redistribution structure rds2, as described below.

The second redistribution structure rds2 may be arranged in the fan-in region FI and the fan-out region FO. The second redistribution structure rds2 may include a second redistribution layer 32 and a second redistribution insulating layer 34. The second redistribution structure rds2 may have a second width TW2. The second width TW2 of the second redistribution structure rds2 may be less than the first width TW1 of the first redistribution structure rds1. The second width TW2 of the second redistribution structure rds2 may be in a range of tens of mm to hundreds of mm. The second redistribution layer 32 may be formed inside the second redistribution insulating layer 34. The second redistribution layer 32 may be insulated by the second redistribution insulating layer 34.

The second redistribution layer 32 may include multiple layers inside the second redistribution insulating layer 34. The second redistribution layer 32 may include, for example, a metal layer including a material, such as copper, nickel, stainless steel, and beryllium copper. The second redistribution insulating layer 34 may include an insulating polymer or an insulating material containing silicon. Examples of the insulating polymer or the insulating material containing silicon have been described above, and thus, the descriptions thereof are omitted.

The second redistribution structure rds2 may include a third connection pad 36 and a second redistribution bonding pad 38. The third connection pad 36 may be positioned at an upper portion of the second redistribution structure rds2. The third connection pad 36 may be positioned in the fan-in region FI. The third connection pad 36 may be a portion of the second redistribution layer 32. As described below, the third connection pad 36 may be exposed through a first connection hole 42 formed in the second molding layer 40.

The second redistribution bonding pad 38 may be positioned at the upper portion of the second redistribution structure rds2. The second redistribution bonding pad 38 may be positioned in the fan-out region FO. The second redistribution bonding pad 38 may be formed in some or all fan-out regions FO on both sides of the fan-in region FI. The second redistribution bonding pad 38 may be a portion of the second redistribution layer 32. The second redistribution bonding pad 38 may be a pad to which the bonding wire 28 is bonded.

The bonding wire 28 may electrically connect the second redistribution bonding pad 38 and the first redistribution bonding pad 18 to each other. The bonding wire 28 may electrically connect the second redistribution structure rds2 and the first redistribution structure rds1 to each other. The bonding wire 28 may be a metal wire, such as a gold wire or a copper wire.

The bonding wire 28 may have a second height H2 from an upper surface of the second redistribution structure rds2. The second height H2 of the bonding wire 28 may be in a range of tens of micrometers (μm) to hundreds of μm. In some example embodiments, the second height H2 of the bonding wire 28 may be about 10 μm to about 100 μm.

In this regard, when the second redistribution structure rds2 and the first redistribution structure rds1 are connected to each other by a meter pillar (or a metal post), the height of the metal pillar may be in a range of hundreds of μm. Because a large number of plating processes may be performed on a metal pillar of several hundreds of μm, a long process time and a high process defect rate may occur.

On the contrary, when the second redistribution structure rds2 and the first redistribution structure rds1 are connected to each other by the bonding wire 28 as in the inventive concepts, the bonding wire process takes less time and a defect rate is limited or suppressed. Thus, the second redistribution structure rds2 and the first redistribution structure rds1 may be electrically connected to each other with reliability. In addition, even when the pitches of the first redistribution bonding pad 18 and the second redistribution bonding pad 38 are reduced, the first redistribution bonding pad 18 and the second redistribution bonding pad 38 may be easily connected to each other by the bonding wire 28.

The second molding layer 40 may mold the first semiconductor chip ch1, the second redistribution structure rds2, the bonding wire 28, and the first molding layer 30 on the first redistribution structure rds1. The second molding layer 40 may include an insulating polymer. The second molding layer 40 may include a material that is different from that of the first molding layer 30. In some example embodiments, the second molding layer 40 may include an EMC. The first molding layer 30 and the second molding layer 40 may configure the molding structures.

The first connection hole 42 exposing the third connection pad 36 may be arranged in the second molding layer 40 on the second redistribution structure rds2. A plurality of first connection holes 42 may be provided. As shown in FIG. 2, a first height H1 (or thickness) of the second molding layer 40 on the second redistribution structure rds2 may be in a range of tens of μm to hundreds of μm.

In some example embodiments, the first height H1 (or the thickness) of the second molding layer 40 on the second redistribution structure rds2 may be in a range of about 20 μm to about 500 μm. The first connection hole 42 may be formed by removing part of the second molding layer 40 formed on the second redistribution structure rds2 by using a laser drilling method.

Each of the plurality of first connection holes 42 may expose one third connection pad 36. As shown in FIG. 2, the first connection hole 42 may have an upper width W1 and a lower width W2. The upper width W1 of the first connection hole 42 may be greater than the lower width W2 thereof. The upper width W1 and the lower width W2 of the first connection hole 42 may each be in a range of tens of μm to hundreds of μm. In some example embodiments, the upper width W1 and the lower width W2 of the first connection hole 42 may each be in a range of about 50 μm to about 500 μm.

Both sidewalls SL1 and SL2 of the first connection hole 42 may be inclined. The absolute values of the inclination degrees of the both sidewalls SL1 and SL2 of the first connection hole 42 may be equal or substantially equal to each other. The third connection pad 36 exposed by the first connection hole 42 may be electrically connected to an upper semiconductor package through a second external connection terminal, as described below.

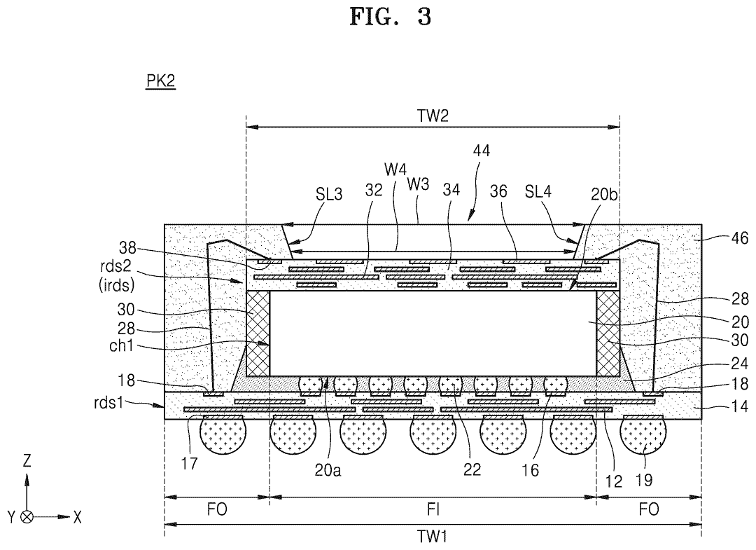

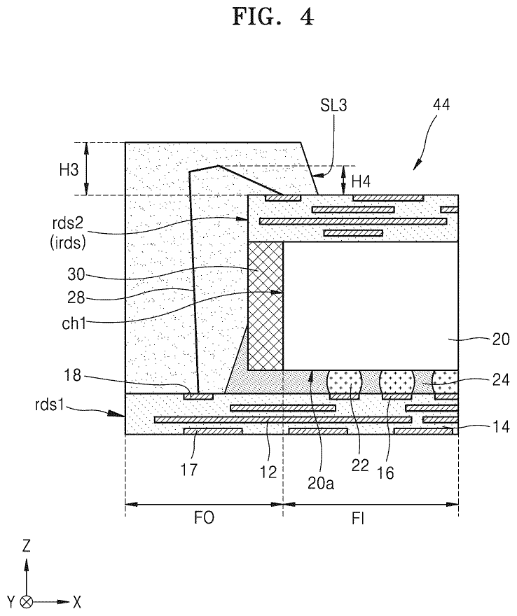

FIG. 3 is a cross-sectional view of a semiconductor package according to an example embodiment, and FIG. 4 is an enlarged view of a portion of the semiconductor package of FIG. 3.

In particular, as compared to the semiconductor package PK1 of FIGS. 1 and 2, a semiconductor package PK2 further includes an underfill layer 24 on a lower portion of the first semiconductor chip ch1. The underfill layer 24 may include an insulating polymer. Compared to the semiconductor package PK1 of FIGS. 1 and 2, the semiconductor package PK2 includes a second connection hole 44 exposing the plurality of third connection pads 36 on the second redistribution structure rds2.

The semiconductor package PK2 may be substantially the same as the semiconductor package PK1 except for the underfill layer 24 and the second connection hole 44. In FIGS. 3 and 4, descriptions previously given with reference to FIGS. 1 and 2 are briefly given or omitted.

The semiconductor package PK2 may include the first redistribution structure rds1, the first semiconductor chip ch1, the underfill layer 24, the second redistribution structure rds2, the bonding wire 28, a first molding layer 30 and a second molding layer 46, and the second connection hole 44.

The molding layers 30 and 46 may include the first molding layer 30 formed on each of both sidewalls of the first semiconductor chip ch1, and the second molding layer 46 molding the first semiconductor chip ch1, the second redistribution structure rds2, the bonding wire 28, and the first molding layer 30. The second molding layer 46 may correspond to the second molding layer 40 of FIGS. 1 and 2.

For example, the first molding layer 30 and the second molding layer 46 may each include an EMC. The underfill layer 24 may be arranged below the first semiconductor chip ch1 and below the first molding layer 30. The underfill layer 24 may support the first chip connection terminal 22 on the first redistribution structure rds1.

The bonding wire 28 may electrically connect the second redistribution bonding pad 38 and the first redistribution bonding pad 18 to each other. As shown in FIG. 4, the bonding wire 28 may have a fourth height H4 from an upper surface of the second redistribution structure rds2. The fourth height H4 of the bonding wire 28 may be in a range of tens of μm to hundreds of μm. In some example embodiments, the fourth height H4 of the bonding wire 28 may be in a range of about 10 μm to about 100 μm.

The second connection hole 44 exposing the third connection pad 36 may be arranged in the second molding layer 46 on the second redistribution structure rds2. One second connection hole 44 may be provided. As shown in FIG. 4, a third height H3 (or thickness) of the second molding layer 46 on the second redistribution structure rds2 may be in a range of tens of μm to hundreds of μm.

In some example embodiments, the third height H3 (or the thickness) of the second molding layer 46 on the second redistribution structure rds2 may be in a range of about 20 μm to about 500 μm. The second connection hole 44 may be formed by removing only a portion of the second molding layer 40 on the second redistribution structure rds2.

The second connection hole 44 may expose the plurality of third connection pads 36. The second connection hole 44 may have an upper width W3 and a lower width W4. The upper width W3 of the second connection hole 44 may be greater than the lower width W4 thereof. The upper width W3 and the lower width W4 of the second connection hole 44 may each be in a range of several mm to several tens of mm.

Both sidewalls SL3 and SL4 of the second connection hole 44 may be inclined. The absolute values of the inclination degrees of the both sidewalls SL3 and SL4 of the second connection hole 44 may be equal or substantially equal to each other. The third connection pad 36 exposed by the second connection hole 44 may be electrically connected to an upper semiconductor package through a second external connection terminal, as described below.

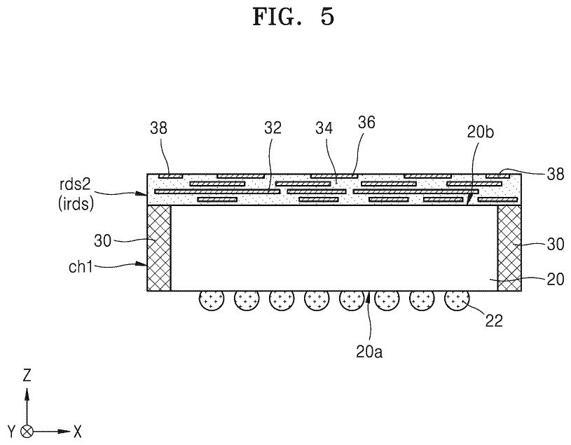

FIGS. 5 to 9 are cross-sectional views for explaining a method of manufacturing the semiconductor package PK1 of FIGS. 1 and 2.

In particular, FIGS. 5 to 9 are provided to explain the method of manufacturing the semiconductor package PK1 of FIGS. 1 and 2. In FIGS. 5 to 9, descriptions already given with reference to FIGS. 1 and 2 are briefly given or omitted.

Referring to FIG. 5, FIG. 5 illustrates that the first semiconductor chip ch1, the first molding layer 30, and the second redistribution structure rds2 are formed. The first molding layer 30 is formed on each of both side surfaces of the first semiconductor chip ch1. The first semiconductor chip ch1 may include the first semiconductor substrate 20. The first semiconductor substrate 20 may have the lower surface 20a and the upper surface 20b. The lower surface 20a of the first semiconductor substrate 20 may be an active surface, and the upper surface 20b of the first semiconductor substrate 20 may be an inactive surface.

Then, the second redistribution structure rds2 is formed on the first semiconductor chip ch1 and the first molding layer 30. The second redistribution structure rds2 may be an interposer redistribution structure irds. The second redistribution structure rds2 may include the second redistribution layer 32, the second redistribution insulating layer 34, the third connection pad 36, and the second redistribution bonding pad 38.

Subsequently, the first chip connection terminal 22 is formed on a lower portion of the first semiconductor chip ch1. The first chip connection terminal 22 may include at least one of a solder, a bump, and a pillar.

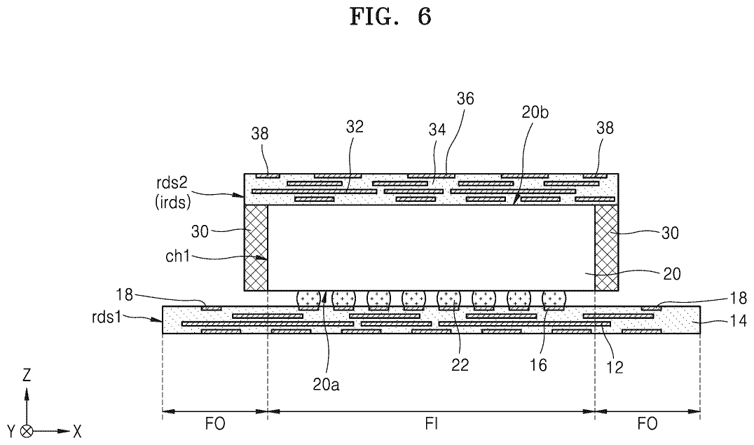

Referring to FIG. 6, the first redistribution structure rds1 having the fan-in region FI and the fan-out region FO is prepared. The first redistribution structure rds1 may be obtained by forming the first redistribution structure rds1 on a carrier substrate and then removing the carrier substrate.

The first redistribution structure rds1 may include the first redistribution layer 12, the first redistribution insulating layer 14, the first connection pad 16, the second connection pad 17, and the first redistribution bonding pad 18.

Subsequently, the first semiconductor chip ch1, the first molding layer 30, and the second redistribution structure rds2 are mounted on the first redistribution structure rds1 through the first chip connection terminal 22. The first redistribution structure rds1 and the first semiconductor chip ch1 are electrically connected to each other by mounting the first chip connection terminal 22 on the first connection pad 16.

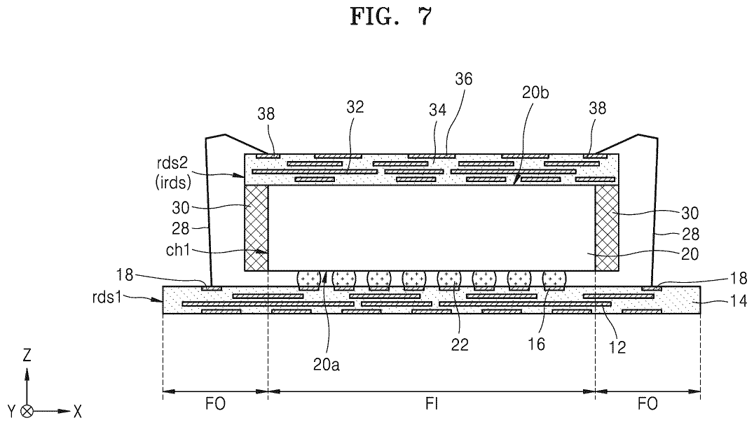

Referring to FIG. 7, the second redistribution bonding pad 38 of the second redistribution structure rds2 is connected to the first redistribution bonding pad 18 of the first redistribution structure rds1 through the bonding wire 28.

As described above, in some example embodiments of the inventive concepts, the second redistribution structure rds2 and the first redistribution structure rds1 are connected to each other by the bonding wire 28 instead of a metal pillar (or a metal post). Accordingly, the second redistribution structure rds2 and the first redistribution structure rds1 may be electrically connected to each other with reliability.

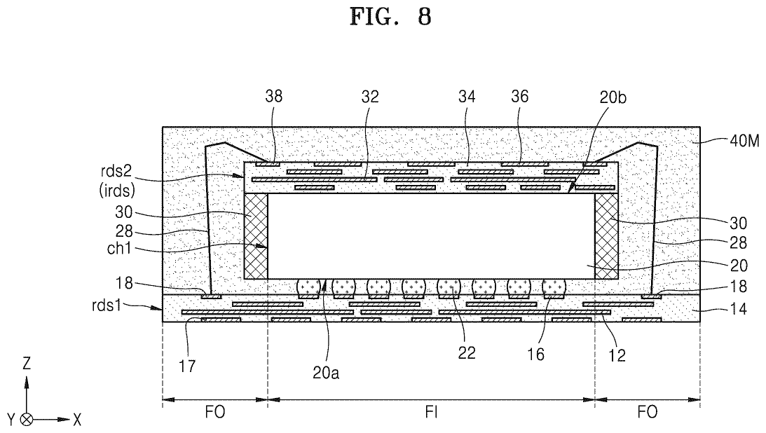

Referring to FIG. 8, a second molding material layer 40M molds the first semiconductor chip ch1, the second redistribution structure rds2, the bonding wire 28, and the first molding layer 30 on the first redistribution structure rds1. The second molding material layer 40M may be formed between the first chip connection terminals 22, on a lower portion of the first semiconductor chip ch1 and the first molding layer 30, on both side portions of the first molding layer 30, and on an upper portion of the second redistribution structure rds2.

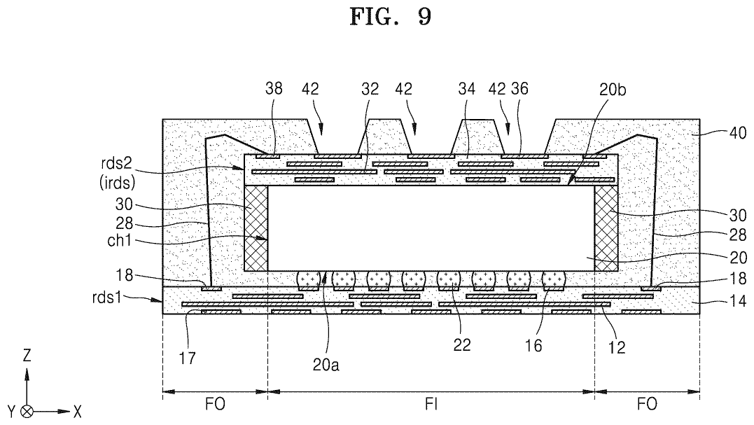

Referring to FIG. 9, the first connection hole 42 exposing the third connection pad 36 is formed in the second molding layer 40 on the second redistribution structure rds2. The first connection hole 42 is formed by removing part of the second molding material layer 40M of FIG. 8 formed on the second redistribution structure rds2 by using a laser drilling method.

Accordingly, the second molding material layer 40M of FIG. 8 may become the second molding layer 40 having the first connection hole 42. The shape of the first connection hole 42 has been described with reference to FIG. 2, and thus, descriptions thereof are omitted. Through such a manufacturing process, the semiconductor package PK1 of FIGS. 1 and 2 may be manufactured.

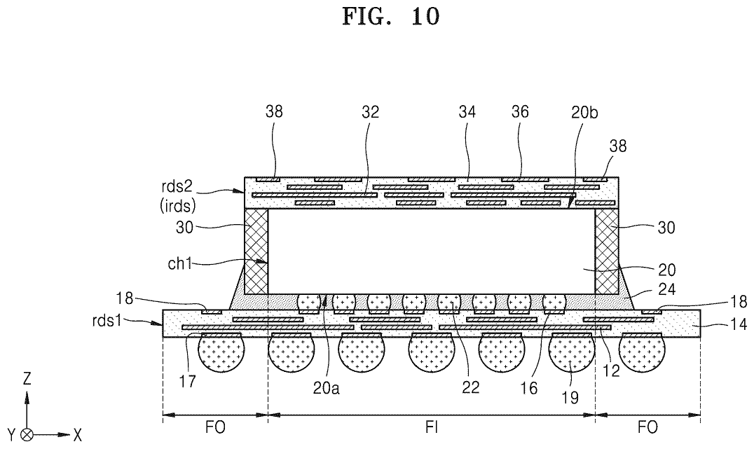

FIGS. 10 to 12 are cross-sectional views for explaining a method of manufacturing the semiconductor package PK2 of FIGS. 3 and 4.

In particular, FIGS. 10 to 12 are provided to explain the method of manufacturing the semiconductor packaged PK2 of FIGS. 3 and 4. In FIGS. 10 to 12, descriptions already given with reference to FIGS. 3 and 4 are briefly given or omitted.

First, the manufacturing process of FIGS. 5 and 6 as described above is performed. In some example embodiments, the first semiconductor chip ch1, the first molding layer 30, and the second redistribution structure rds2 are mounted on the first redistribution structure rds1 through the first chip connection terminal 22.

Referring to FIG. 10, the underfill layer 24 is formed on the lower portion of the first semiconductor chip ch1 and the lower portion of the first molding layer 30. The underfill layer 24 may support the first chip connection terminal 22 on the first redistribution structure rds1. The underfill layer 24 is formed to fix and support the first semiconductor chip ch1 and the first molding layer 30 on the first redistribution structure rds1.

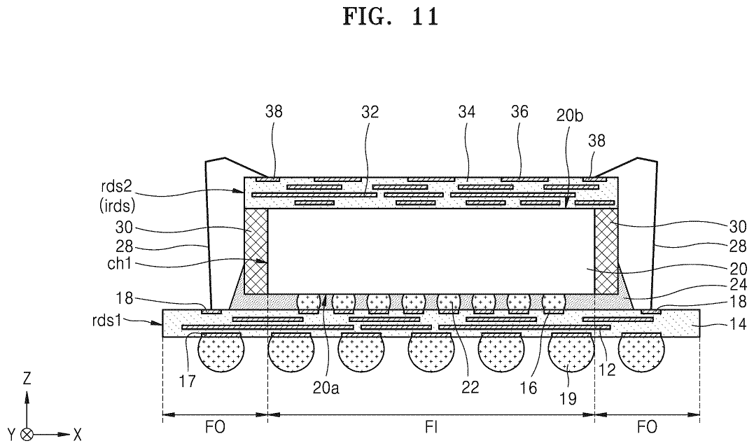

Referring to FIG. 11, the second redistribution bonding pad 38 of the second redistribution structure rds2 is connected to the first redistribution bonding pad 18 of the first redistribution structure rds1 through the bonding wire 28.

As described above, in some example embodiments of the inventive concepts, the second redistribution structure rds2 and the first redistribution structure rds1 are connected to each other by the bonding wire 28 instead of a metal pillar (or a metal post). Accordingly, the second redistribution structure rds2 and the first redistribution structure rds1 may be electrically connected to each other with reliability.

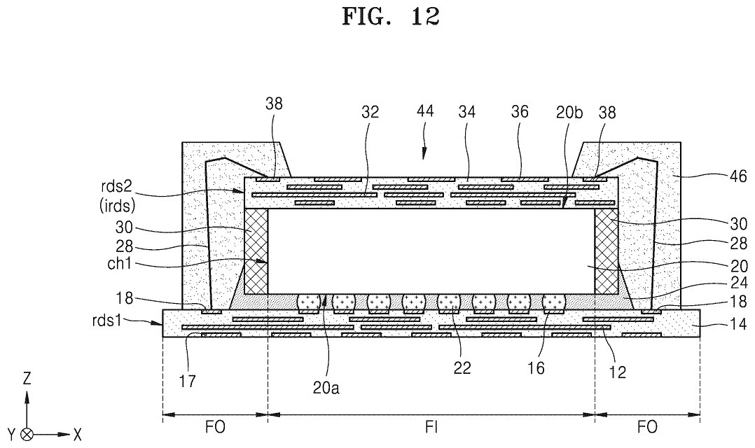

Referring to FIG. 12, the second molding layer 46 molds the first semiconductor chip ch1, the second redistribution structure rds2, the bonding wire 28, and the first molding layer 30 on the first redistribution structure rds1, and the second connection hole 44 is also in the second redistribution structure rds2.

The second connection hole 44 may expose the plurality of third connection pads 36. The second connection hole 44 may be provided by forming the second molding layer 46 only on a portion of the second redistribution structure rds2 without using a laser drilling process. Through such a manufacturing process, the semiconductor package PK2 of FIGS. 3 and 4 may be manufactured.

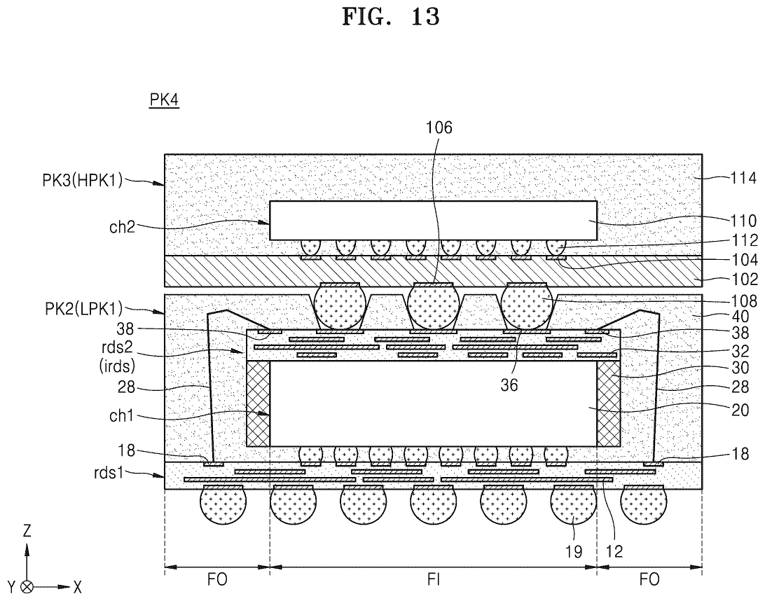

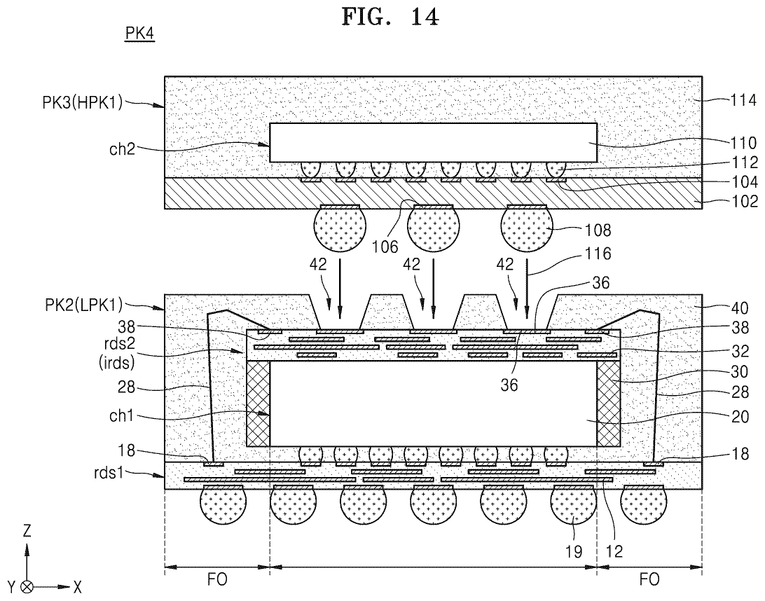

FIG. 13 is a cross-sectional view of a semiconductor package according to an example embodiment, and FIG. 14 is a cross-sectional view for explaining a method of manufacturing the semiconductor package of FIG. 13.

In particular, a semiconductor package PK4 includes an upper semiconductor package HPK1 mounted on a lower semiconductor package LPK1, as shown in FIG. 13. FIG. 14 illustrates a process in which the upper semiconductor package HPK1 is mounted on the lower semiconductor package LPK1. The semiconductor package PK4 may have a package-on-package structure.

The lower semiconductor package LPK1 may be the semiconductor package PK1 shown in FIGS. 1 and 2. The lower semiconductor package LPK1 may be as described with reference to FIGS. 1 and 2, and thus, the lower semiconductor package LPK1 is briefly described here. The lower semiconductor package LPK1 may include the first redistribution structure rds1, the first semiconductor chip ch1, the second redistribution structure rds2, the bonding wire 28, and the molding layers 30 and 40.

The upper semiconductor package HPK1 may be a semiconductor package PK3. The semiconductor package PK3 may include a wire substrate 102, a second semiconductor chip ch2, a second chip connection terminal 112, an upper molding layer 114, and a second external connection terminal 108.

The wire substrate 102 may be a printed circuit board. An upper wire pad 104 and a lower wire pad 106 may be respectively arranged on an upper surface and a lower surface of the wire substrate 102. The second external connection terminal 108 may be connected to the lower wire pad 106. The second external connection terminal 108 may be electrically connected to the third connection pad 36 of the second redistribution structure rds2.

The second semiconductor chip ch2 may include a second semiconductor substrate 110. The second semiconductor substrate 110 may include the same or substantially the same material as that of the first semiconductor substrate 20 of FIGS. 1 and 2. The second semiconductor chip ch2 may be electrically connected to the wire substrate 102 through the second chip connection terminal 112. In an example embodiment, the second semiconductor chip ch2 is connected to the wire substrate 102 through the second chip connection terminal 112, but the second semiconductor chip ch2 may also be connected to the wire substrate 102 through a bonding wire.

The second semiconductor chip ch2 may be, for example, a memory semiconductor chip. The memory semiconductor chip may be, for example, a volatile memory semiconductor chip, such as dynamic random access memory (DRAM) or static random access memory (SRAM), or a nonvolatile memory semiconductor chip, such as phase-change random access memory (PRAM), magnetoresistive random access memory (MRAM), ferroelectric random access memory (FeRAM), or resistive random access memory (RRAM), but example embodiments are not limited thereto.

As shown in FIG. 14, the semiconductor package PK4 may be manufactured by moving the second external connection terminal 108 of the upper semiconductor package HPK1 to the third connection pad 36 exposed by the first connection hole 42 formed in the lower semiconductor package LPK1 in an arrow direction 116. The second external connection terminal 108 of the upper semiconductor package HPK1 may be connected to the third connection pad 36 of the lower semiconductor package LPK1 by a thermal compression bonding method.

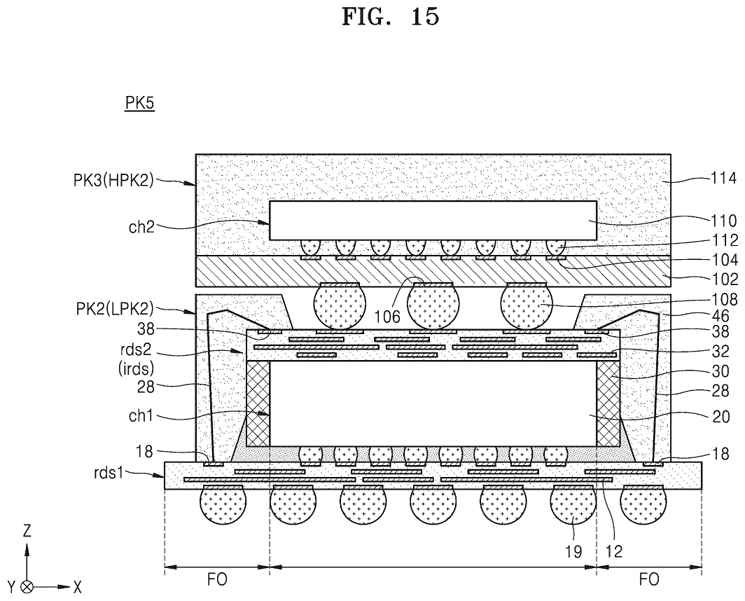

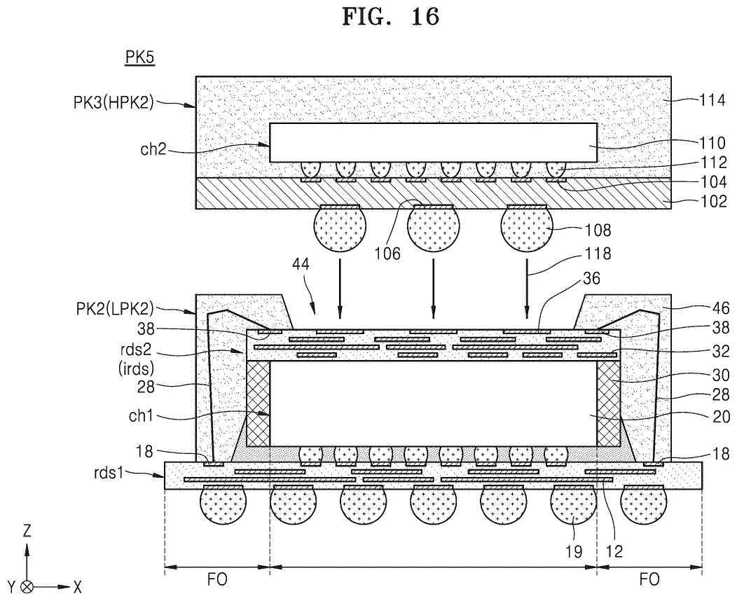

FIG. 15 is a cross-sectional view of a semiconductor package according to an example embodiment, and FIG. 16 is a cross-sectional view for explaining a method of manufacturing the semiconductor package of FIG. 15.

In particular, a semiconductor package PK5 may include an upper semiconductor package HPK2 mounted on a lower semiconductor package LPK2, as shown in FIG. 15. FIG. 16 illustrates a process in which the upper semiconductor package HPK2 is mounted on the lower semiconductor package LPK2. The semiconductor package PK5 may have a package-on-package structure.

The lower semiconductor package LPK2 may be the semiconductor package PK2 shown in FIGS. 3 and 4. The lower semiconductor package LPK2 may be as described with reference to FIGS. 3 and 4, and thus, the lower semiconductor package LPK2 is briefly described here. The lower semiconductor package LPK2 may include the first redistribution structure rds1, the first semiconductor chip ch1, the second redistribution structure rds2, the bonding wire 28, the underfill layer 24, and the molding layers 30 and 46.

The upper semiconductor package HPK2 may be the semiconductor package PK3. The semiconductor package PK3 may include the wire substrate 102, the second semiconductor chip ch2, the second chip connection terminal 112, the upper molding layer 114, and the second external connection terminal 108. The semiconductor package PK3 may be as previously described with reference to FIGS. 13 and 14, and thus, redundant descriptions thereof are omitted.

The upper wire pad 104 and the lower wire pad 106 may be respectively arranged on an upper surface and a lower surface of the wire substrate 102. The second external connection terminal 108 may be connected to the lower wire pad 106. The second external connection terminal 108 may be electrically connected to the third connection pad 36 of the second redistribution structure rds2.

As shown in FIG. 16, the semiconductor package PK5 may be manufactured by moving the second external connection terminal 108 of the upper semiconductor package HPK1 to the third connection pad 36 exposed by the second connection hole 44 formed in the lower semiconductor package LPK2 in an arrow direction 118. The second connection hole 44 may expose the plurality of third connection pads 36. The second external connection terminal 108 of the upper semiconductor package HPK2 may be connected to the third connection pad 36 of the lower semiconductor package LPK2 by a thermal compression bonding method.

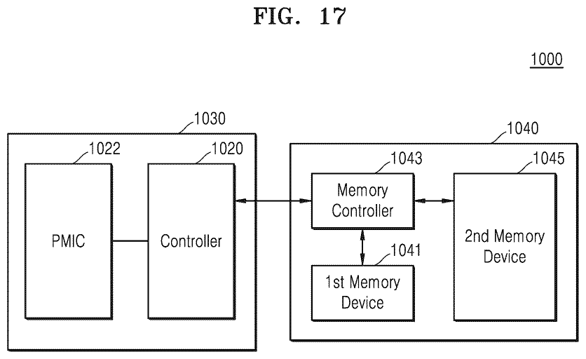

FIG. 17 is a block diagram illustrating a configuration of a semiconductor package according to an example embodiment.

In particular, a semiconductor package 1000 may include any one of the semiconductor packages PK4 and PK5 of the example embodiments of the inventive concepts. The semiconductor package 1000 may include a controller (or controller chip) 1020, a first memory device (or a first memory chip) 1041, a second memory device (or a second memory chip) 1045, and a memory controller 1043. The semiconductor package 1000 may further include a power management integrated circuit (PMIC) 1022 respectively supplying currents of operating voltages to the controller 1020, the first memory device 1041, the second memory device 1045, and the memory controller 1043. The operating voltages applied to respective components may be designed to be identical to each other or different from each other.

A lower semiconductor package 1030 including the controller 1020 and the PMIC 1022 may be any one of the lower semiconductor packages LPK1 and LPK2 of the example embodiments of the inventive concepts described above. An upper semiconductor package 1040 including the first memory device 1041, the second memory device 1045, and the memory controller 1043 may be the upper semiconductor package HPK2 of the example embodiments of the inventive concepts described above.

The semiconductor package 1000 may be implemented to be included in a personal computer (PC) or a mobile device. The mobile device may be implemented as a laptop computer, a mobile phone, a smartphone, a tablet PC, a personal digital assistant (PDA), an enterprise digital assistant (EDA), a digital still camera, a digital video camera, a portable multimedia player (PMP), a personal navigation device or portable navigation device (PND), a handheld game console, a mobile Internet device (MID), a wearable computer, an Internet of Things (IoT) device, an Internet of Everything (IoE) device, or a drone, but example embodiments are not limited thereto.

The controller 1020 may control an operation of each of the first memory device 1041, the second memory device 1045, and the memory controller 1043. For example, the controller 1020 may be implemented by an integrated circuit (IC), a system on chip (SoC), an AP, a mobile AP, a chipset, or a set of chips. The controller 1020 may include a central processing unit (CPU), a graphics processing unit (GPU), and/or a modem. In some example embodiments, the controller 1020 may perform functions of a modem and an AP.

The memory controller 1043 may control the second memory device 1045 under control by the controller 1020. The first memory device 1041 may be implemented by a volatile memory device. The volatile memory device may be implemented by random access memory (RAM), dynamic RAM (DRAM), or static RAM (SRAM), but is not limited thereto. The second memory device 1045 may be implemented by a storage memory device. The storage memory device may be implemented by a nonvolatile memory device.

The storage memory device may be implemented as a flash-based memory device, but is not limited thereto. The second memory device 1045 may be implemented as a NAND-type flash memory device. The NAND-type flash memory device may include a two-dimensional (2D) memory cell array or a three-dimensional (3D) memory cell array. The 2D memory cell array or the 3D memory cell array may include a plurality of memory cells, and each of the plurality of memory cells may store 1-bit information or 2-bit or more information, but example embodiments are not limited thereto.

When the second memory chip 1045 is implemented as a flash-based memory device, the memory controller 1043 may use a multimedia card (MMC) interface, an embedded MMC (eMMC) interface, or a universal flash storage (UFS) interface, but is not limited thereto.

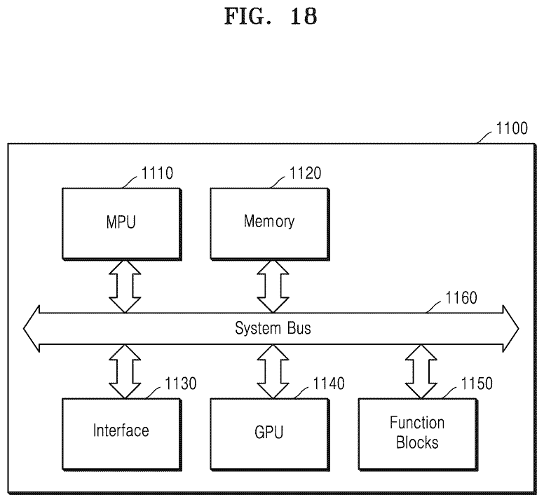

FIG. 18 is a block diagram schematically illustrating a configuration of a semiconductor package according to an example embodiment.

In particular, a semiconductor package 1100 may include a micro processing unit (MPU) 1110, a memory 1120, an interface 1130, a GPU 1140, a plurality of functional blocks 1150, and a bus 1160 connecting these components. The semiconductor package 1100 may include both the MPU 1110 and the GPU 1140, or may include only one of the two.

The MPU 1110 may include a core and an L2 cache. For example, the MPU 1110 may include a multicore. Cores of the multicore may have the same function or different functions. Also, the cores of the multicore may be simultaneously activated, or may be activated at different times. The memory 1120 may store results processed by the plurality of functional blocks 1150 under control by the MPU 1110. For example, when contents stored in the L2 cache are flushed, the MPU 1110 may store the contents in the memory 1120. The interface 1130 may interface with external devices. For example, the interface 1130 may interface with a camera, a liquid-crystal display (LCD), a speaker, or the like.

The GPU 1140 may perform graphics functions. For example, the GPU 1140 may perform video codec, or may process 3D graphics. The plurality of functional blocks 1150 may perform various functions. For example, when the semiconductor package 1100 is an AP used in a mobile device, some of the functional blocks 1150 may perform a communication function.

The semiconductor package 1100 may be the semiconductor packages PK4 and PK5 previously described in example embodiments of the inventive concepts. The MPU 1110 and/or the GPU 1140 may be the lower semiconductor packages LPK1 and LPK2 described above. The memory 1120 may be the upper semiconductor package HPK2 described above. The interface 1130 and the plurality of functional blocks 1150 may correspond to portions of the lower package lower semiconductor packages LPK1 and LPK2 described above.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value include a tolerance of ±10% around the stated numerical value. When ranges are specified, the range includes all values therebetween such as increments of 0.1%.

One or more of the elements disclosed above may include or be implemented in one or more processing circuitries such as hardware including logic circuits; a hardware/software combination such as a processor executing software; or a combination thereof. For example, the processing circuitries more specifically may include, but is not limited to, a central processing unit (CPU), an arithmetic logic unit (ALU), a digital signal processor, a microcomputer, a field programmable gate array (FGPA), a System-on-Chip (SoC), a programmable logic unit, a microprocessor, application-specific integrated circuit (ASIC), etc.

While some example embodiments of the inventive concepts have been particularly shown and described with reference to embodiments thereof, it will be understood that various changes in form and details may be made therein without departing from the scope of the inventive concepts.

What is claimed is:

1. A semiconductor package comprising:
a first redistribution structure comprising a first redistribution layer and a first redistribution bonding pad, the first redistribution bonding pad electrically connected to the first redistribution layer;
a first semiconductor chip on the first redistribution structure;
a second redistribution structure on the first semiconductor chip, the second redistribution structure comprising a second redistribution layer and a second redistribution bonding pad, the second redistribution layer electrically connected to the second redistribution layer;
a bonding wire electrically connecting the second redistribution bonding pad and the first redistribution bonding pad to each other; and
a molding layer covering at least a portion the first semiconductor chip, the second redistribution structure, and the bonding wire on the first redistribution structure.

2. The semiconductor package of claim 1, wherein a second width of the second redistribution structure is less than a first width of the first redistribution structure.

3. The semiconductor package of claim 1, wherein
the first redistribution bonding pad is at an upper portion of the first redistribution structure, and
the second redistribution bonding pad is at an upper portion of the second redistribution structure.

4. The semiconductor package of claim 1, wherein
the first semiconductor chip includes at least two side surfaces,
the molding layer comprises a first molding layer on each of the at least two side surfaces of the first semiconductor chip, and a second molding layer covering at least a portion the first semiconductor chip, and
the first molding layer, the second redistribution structure, and the bonding wire are on the first redistribution structure.

5. The semiconductor package of claim 4, wherein the second redistribution structure is on an upper surface of the first molding layer and an upper surface of the first semiconductor chip.

6. The semiconductor package of claim 1, further comprising a first connection pad at an upper portion of the first redistribution structure, and a second connection pad at a lower portion of the first redistribution structure, wherein,
the first connection pad is connected to a first chip connection terminal, and
the second connection pad is connected to a first external connection terminal.

7. The semiconductor package of claim 1, further comprising:
a third connection pad at an upper portion of the second redistribution structure; and
a connection hole in the molding layer, the connection hole exposing the third connection pad.

8. The semiconductor package of claim 1, further comprising:
a first chip connection terminal arranged on a lower portion of the first semiconductor chip, the first chip connection terminal connected to the first redistribution structure; and
an underfill layer supporting the first chip connection terminal, the underfill layer on the lower portion of the first semiconductor chip.

9. A semiconductor package comprising:
a first redistribution structure including a fan-in region and a fan-out region, the fan-in region including at least two sides and the fan-out region on each of the at least two sides of the fan-in region, the first redistribution structure comprising a first redistribution insulating layer, a first redistribution layer insulated by the first redistribution insulating layer, and a first redistribution bonding pad electrically connected to the first redistribution layer, the first redistribution bonding pad on an upper portion of the first redistribution insulating layer in the fan-out region;
a first semiconductor chip on the first redistribution structure in the fan-in region;
a second redistribution structure on the first semiconductor chip in the fan-in region and the fan-out region, the second redistribution structure comprising a second redistribution insulating layer, a second redistribution layer insulated by the second redistribution insulating layer, and a second redistribution bonding pad electrically connected to the second redistribution layer, the second redistribution layer on an upper portion of the second redistribution insulating layer in the fan-out region;
a bonding wire electrically connecting the second redistribution bonding pad in the fan-out region and the first redistribution bonding pad in the fan-out region to each other; and
a molding layer covering at least a portion of the first semiconductor chip, the second redistribution structure, and the bonding wire on the first redistribution structure in the fan-in region and the fan-out region.

10. The semiconductor package of claim 9, wherein
a second width of the second redistribution structure is less than a first width of the first redistribution structure,
the first redistribution bonding pad is at an upper portion of the first redistribution structure, and
the second redistribution bonding pad is at an upper portion of the second redistribution structure.

11. The semiconductor package of claim 9, wherein
the first semiconductor chip includes at least two side surfaces,
the molding layer comprises a first molding layer on each of the at least two side surfaces of the first semiconductor chip in the fan-out region, and
the molding layer comprises a second molding layer covering at least a portion of the first semiconductor chip, the first molding layer, the second redistribution structure, and the bonding wire on the first redistribution structure in the fan-in region and the fan-out region.

12. The semiconductor package of claim 11, wherein
the second redistribution structure is on an upper surface of the first molding layer and an upper surface of the first semiconductor chip,
the second redistribution structure further comprises a third connection pad at an upper portion of the second redistribution structure, and
the molding layer further comprises a connection hole exposing the third connection pad.

13. The semiconductor package of claim 9, further comprising a first connection pad at an upper portion of the first redistribution structure and a second connection pad at a lower portion of the first redistribution structure, wherein,
the first connection pad is connected to a first chip connection terminal, and
the second connection pad is connected to a first external connection terminal.

14. The semiconductor package of claim 9, further comprising:
a first chip connection terminal arranged on a lower portion of the first semiconductor chip, the first chip connection terminal connected to the first redistribution structure; and
an underfill layer arranged on the lower portion of the first semiconductor chip, the underfill layer supporting the first chip connection terminal.

15. A semiconductor package comprising:
a first redistribution structure including a fan-in region and a fan-out region, the fan-in region including at least two sides, and the fan-out region on each of the at least two sides of the fan-in region, the first redistribution structure comprising a first redistribution insulating layer, a first redistribution layer insulated by the first redistribution insulating layer, a first connection pad electrically connected to the first redistribution layer in the fan-in region, and a first redistribution bonding pad electrically connected to the first redistribution layer in the fan-out region;
a first semiconductor chip on the first redistribution structure in the fan-in region, the first semiconductor chip electrically connected to the first connection pad through a first chip connection terminal;
a second redistribution structure on the first semiconductor chip in the fan-in region and the fan-out region, the second redistribution structure comprising a second redistribution insulating layer, a second redistribution layer insulated by the second redistribution insulating layer, a third connection pad electrically connected to the second redistribution layer in the fan-in region, and a second redistribution bonding pad electrically connected to the second redistribution layer in the fan-out region;
a bonding wire electrically connecting the second redistribution bonding pad in the fan-out region and the first redistribution bonding pad in the fan-out region to each other; and
a molding layer covering at least a portion of the first semiconductor chip, the second redistribution structure, and the bonding wire on the first redistribution structure in the fan-in region and the fan-out region, the molding layer having a connection hole exposing the third connection pad, wherein,
an upper width of the connection hole is greater than a lower width of the connection hole,
the connection hole includes at least two sidewalls, and
the at least two sidewalls of the connection hole are inclined.

16. The semiconductor package of claim 15, further comprising a plurality of third connection pads,
wherein the connection hole is configured to expose the plurality of third connection pads.

17. The semiconductor package of claim 15, further comprising an underfill layer arranged on a lower portion of the first semiconductor chip, the underfill layer supporting the first chip connection terminal.

18. The semiconductor package of claim 15, further comprising:
a second connection pad arranged on a lower portion of the first redistribution structure in the fan-in region and the fan-out region, the second connection pad electrically connected to the first redistribution layer; and
a first external connection terminal connected to the second connection pad.

19. The semiconductor package of claim 15, wherein
the first semiconductor chip includes at least two side surfaces, and
the molding layer comprises a first molding layer on each of the at least two side surfaces of the first semiconductor chip in the fan-out region, and a second molding layer covering at least a portion of the first semiconductor chip, the first molding layer, the second redistribution structure, and the bonding wire on the first redistribution structure in the fan-in region and the fan-out region.

20. The semiconductor package of claim 15, wherein the first redistribution structure, the first semiconductor chip, the second redistribution structure, the bonding wire, and the molding layer define a lower semiconductor package,
the semiconductor package further comprises an upper semiconductor package on the molding layer, wherein the upper semiconductor package comprises a wire substrate, a second semiconductor chip on the wire substrate, an upper molding layer covering at least a portion of the second semiconductor chip on the wire substrate, and a second external connection terminal on a lower portion of the wire substrate, and
the second external connection terminal is in the connection hole and electrically connected to the third connection pad.
